(19) United States
(12) Patent Application Publication
(10) Pub. No.: US 2005/0142836 A1
(43) Pub. Date: Jun. 30, 2005

(54) Method of forming bump pad of flip chip and structure thereof

(75) Inventor: Takayuki Haze, Kyoto-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Samsung Electro-Mechanics Co., Ltd.

(21) Appl. No.: 10/823,297

(22) Filed: Apr. 13, 2004

(30) Foreign Application Priority Data
Dec. 29, 2003 (KR) 2003-99080

(51) Int. Cl. H01L 21/44; H01L 21/48; H01L 21/50

(52) U.S. Cl. 438/613; 438/612; 438/108; 438/665; 438/614

(57) ABSTRACT

Disclosed is a method of forming a bump pad of a flip chip and a structure thereof, characterized in that a resist pattern is formed through coating of a photosensitive material on an electroless copper plating layer, exposure to light and development, and then a bump pad is prepared by pulse plating and direct current plating of the resist pattern, thereby fabricating a substrate with a high density and high reliability.

### BACKGROUND OF THE INVENTION

1. Field of the Invention

The present invention relates, in general, to formation methods of bump pads of flip chips and structures thereof. More particularly, the present invention relates to a method of fabricating a bump pad of a flip chip, characterized in that a photosensitive material is coated on an electroless copper plating layer, exposed to light and developed, to prepare a resist pattern, which is then subjected to pulse plating and direct current plating, to form a bump pad, thereby obtaining a substrate with a high density and high reliability; and a structure of the bump pad of the flip chip.

2. Description of the Related Art

In general, a fabrication method of a semiconductor comprises three steps of manufacturing, packaging, and inspection of a silicon chip. Particularly, it is known that the packaging and inspection steps constitute 70% of total fabrication costs, in which the packaging step greatly affects the size and performance of the chip.

Electronic packaging technology is the manufacturing a semiconductor chip, which is then formed to a system, and has the following functions, that is, signal redistribution, power distribution, mechanical support and protection, and thermal management.

Electronic packaging includes (1) semiconductor chip interconnection, (2) packaging of the semiconductor chip in a single chip module (SCM), (3) bonding of the SCM to a card, such as a PCB, (4) connecting of a plurality of the cards to a board by use of a connector, and (5) preparation of the system.

The techniques of COB (Chip On Board) and MCM (Multi-Chip Module) are in the combined form of the steps (2) and (3), and thus, are referred to as the step (2.5).

As for electronic packaging, the zero step is a chip metallization, and microbonding is mainly employed for the steps (1) and (2).

The chip interconnection of the first step is exemplified by wire bonding, TAB (Tape Automated Bonding), flip chip, and diffusion bonding, and the packaging of the second step includes PTH and SMT.

The bonding process mentioned above is performed at low temperatures so as not to damage the semiconductor circuits.

Among wire bonding, TAB, and flip chip (or C4: Controlled Collapse Chip Connection) of the chip level, the technique of flip chip (C4) is explained, below.

The term “flip chip” is derived from the shape of a bare chip affixed to the substrate using flip-chip style connections.

The flip chip process was developed by IBM in the early 1960s, to substitute for a manual wire bonding having low reliability, and called the C4 at that time.

The flip chip packaging is achieved by the deposition of solder bumps on a metallized portion on an aluminum (Al) pad of the bare chip, and the ball shaping of the deposited solders by means of a reflow soldering.

The solder-mounted bare chip is bonded to the substrate by means of the reflow soldering process. As such, to deposit the solder bumps, the Al pad on the bare chip is metallized by depositing or etching a metal, such as Cr, Au, Ti, Cu, etc., and thus, is surface treated to wet the solders, which is called UBM. (under bump metallurgy).

Upon melting the solders, a passivation is formed around the solder so as to prevent the generation of short circuits by the flow of the wet solders to other positions.

The passivation functions to protect the surface of silicon or circuit from impurities or water, as well as insulation function.

The solder is composed of 95% Pb-5% Sn (Tₘ=315° C.) in cases of ceramic substrates, and a eutectic composition of 37% Pb-63% Sn (Tₘ=183° C.) in cases of the PCB.

The flip chip process, which is used to bond the solder bump by the reflow soldering, can exhibit a self-aligning effect. Further, the pad can be desirably positioned at the inner circuits of the chip under necessity. Thereby, the circuit design can be simplified and the length of the circuit wire can be shortened, thus improving electrical performance.

Also, resistance by the circuit wire decreases and required electrical power and resistant heat can be lowered. Of the packaging methods, the flip chip packaging is the highest with regards to integration density.

The flip chip process, acting to increase the integration density and decrease the consumption of power, is widely applied in communication equipment, and basically constitutes the COB and MCM.

The higher the integration density, the more the heat value per unit area. Thus, a cooling process is regarded as being important. To connect the flip chip with the circuit wire of the substrate, a multi-layer substrate is mainly used, and such connection is achieved by via holes.

With the intention of preventing the solder bonding portion from breaking due to heat stress generated by CTE mismatch of the substrate, the chip and the solder bonding portion, an underfilling process to underfill an epoxy resin between the chip and the substrate is performed, thus decreasing the heat stress and increasing the fatigue life.

Such a flip chip technique is changed from a conventional connecting process using a solder to a connecting process using a conductive adhesive which is advantageous in terms of low price, ultra-fine electrode pitch, an environmental friendly process without the use of a flux, and a low temperature process.

The flip chip technique using the conductive adhesive comprises forming bumps each having a uniform height on a pad, coating a conductive particle-containing adhesive, and bonding a chip to a substrate.

However, the above bump forming process is difficult to perform, because the bumps each are selectively formed at a desired height on every fine pad.

To form the bumps, there are presently exemplified evaporation, sputtering, electroplating, or combinations with a photolithography. In addition, a method of mechanically forming gold stud bumps may be used.

Conventionally, a method of fabricating a high density flip chip mounted pad is classified into the following two.

One of the two, a subtractive method is characterized in that a photosensitive resist is coated on a copper foil or a direct current copper plating layer, after which a resist pattern is formed by exposure to light and development photolithography, and the unnecessary copper is removed by an etching, followed by removing the resist on the remaining circuit.

Concerning the subtractive method, the fabrication of a conventional flip-chip bump pad is shown in FIGS. 1a through 1e.

As shown in FIG. 1a, a copper pad 120 is formed on an insulating material 110 by a copper foil or a direct current copper plating. Then, a photosensitive material 130 comprising a dry film is coated on the copper pad 120, as in FIG. 1b.

In FIG. 1c, the dry film 130 is exposed to light and then developed, to remove a part of the dry film 130 on the copper pad 120, thereby forming a resist pattern 130.

In FIG. 1d, the upper portion of the copper pad 120 formed with the resist pattern 130 is etched, to remove a part of the copper pad 120 formed by the copper foil or direct current copper plating.

Then, as shown in FIG. 1e, the resist pattern 130 is removed, followed by a surface treatment, resulting in a final bump pad.

However, the above method is disadvantageous in that the resulting flip chip pad is trapezoid in shape and has a bottom surface area which is larger than an allowed size, and thus, it is impossible to attain sufficient spaces between the neighboring pads.

The formation of the fine circuit by the above method depends on a copper thickness and a resolution of the resist. However, as for the copper-etching mechanism, an aspect ratio to the copper thickness is 2.0. That is, if the copper thickness is 10 μm, the limit of line/space is 20/20 μm. In this case, the formation of a SMD structured flip chip pad having a diameter of 40 μm results in a pad pitch of maximal 160 μn.

Meanwhile, FIGS. 2a to 2e are sectional views sequentially showing the fabrication of a bump pad, according to another conventional method.

As shown in FIG. 2a, an insulating material 210 is plated via an electroless copper plating to form a thin electroless copper plating layer 220. Then, a dry film 230 is coated on the electroless copper plating layer 220, exposed to light and then developed, to form a resist pattern 230, as seen in FIG. 2b.

As in FIG. 2c, a circuit is formed through an electrolytic copper pulse plating process. Referring to FIG. 2d, the unnecessary resist and electroless copper are removed, thus forming a desired circuit. In FIG. 2e, a surface treatment is applied, thereby obtaining a bump pad as an end product.

The formation of the fine circuit by the above method depends on the uniformity of the insulating layer, the thickness of the electroless copper plating layer, the resolution of the resist, and the deposition of the electrolytic copper plating. However, the limit of line/space is 15/15 μm at present.

In such a case, the formation of a SMD structured flip chip pad having a diameter of 40 μm results in a pad pitch of 100 μm.

However, the electrolytic copper pulse plating process suffers from largely deposited crystal structure. Thus, an intercrystalline etching process by an acid of a post process results in a very uneven surface. Hence, bonding on the flip chip is difficult due to the uneven surface or solder resist remainder with respect to the uneven surface.

### SUMMARY OF THE INVENTION

Therefore, it is an object of the present invention to alleviate the problems encountered in the related art and to provide a method of forming a bump pad of a flip chip, which is advantageous in terms of fine circuits, excellent electrical characteristics, high reliability, high-speed signal transfer structure, and high functionality.

It is another object of the present invention is to provide a structure of the bump pad of the flip chip.

To achieve the above object of the present invention, there is provided a method of forming a bump pad of a flip chip, comprising subjecting a surface of an insulating layer to electroless copper plating to prepare an electroless copper plating layer, which is then coated with a photosensitive material; exposing to light and developing the photosensitive material to prepare a resist pattern, which is then pulse plated to form a pulse plating layer; subjecting the pulse plating layer to electrolytic copper plating using a direct current, to prepare a direct current plating layer; and removing the resist pattern and the electroless copper plating layer.

Further, as for the above method, the electroless copper plating of the insulating layer comprises the formation of the electroless copper plating layer by subjecting the surface of the insulating layer to electroless copper plating, and the coating of the photosensitive material on the electroless copper plating layer.

In addition, a structure of a bump pad of a flip chip comprises a thin electroless copper plating layer patterned on an insulating layer; an electroless layer formed on the thin electroless copper plating layer; and an electrolytic layer formed on the electroless layer.

In the present invention, the electroless layer and the electrolytic layer are total 20 μm thick, and the electrolytic layer using a direct current is 5-10 μm thick.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a through 1e are sectional views sequentially showing the fabrication of a bump pad of a flip chip, according to a conventional technique;

FIGS. 2a through 2e are sectional views sequentially showing the fabrication of a bump pad of a flip chip, according to another conventional technique;

FIGS. 3a through 3f are sectional views sequentially showing the fabrication of a bump pad of a flip chip, according to the present invention; and

FIGS. 4a and 4b are photographs showing a surface and a side surface of a copper plated deposition structure of the bump pad, according to the conventional technique, respectively; and

FIGS. 4c and 4d are photographs showing a surface and a side surface of a copper plated deposition structure of the bump pad, according to the present invention, respectively.

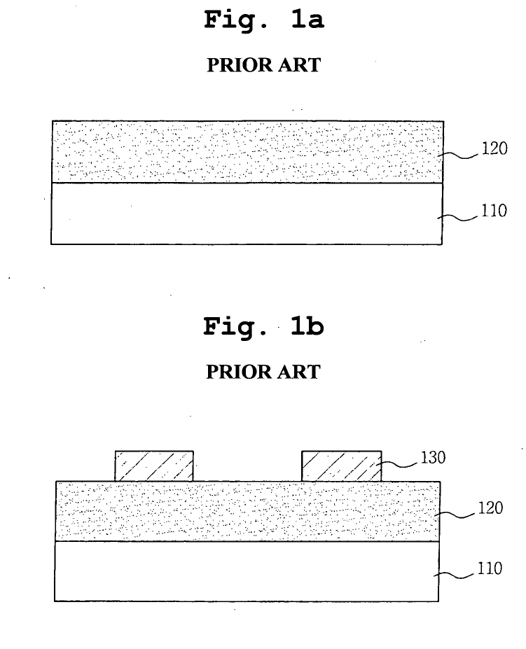

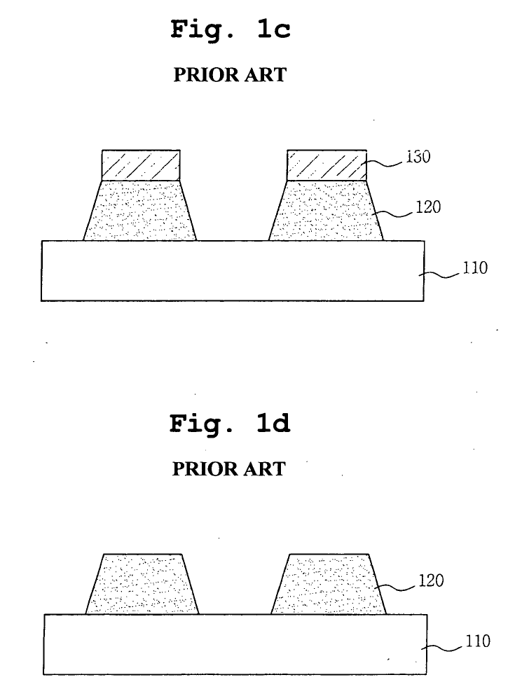

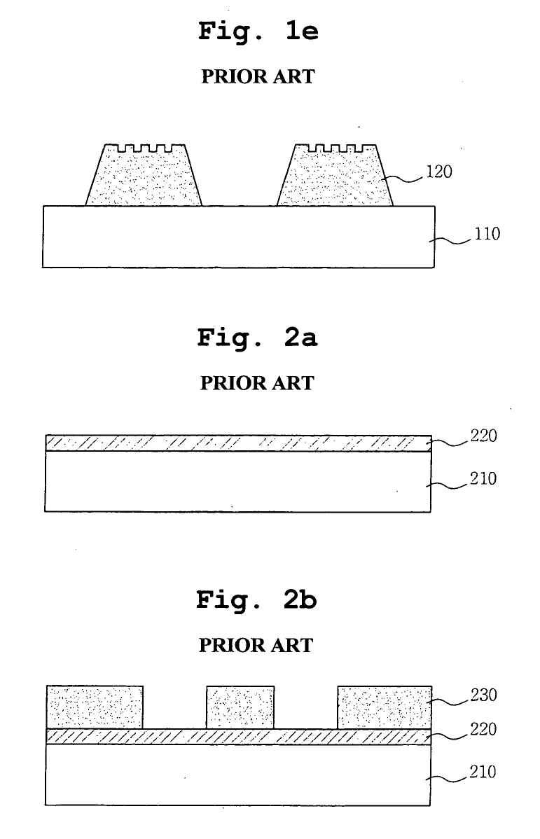

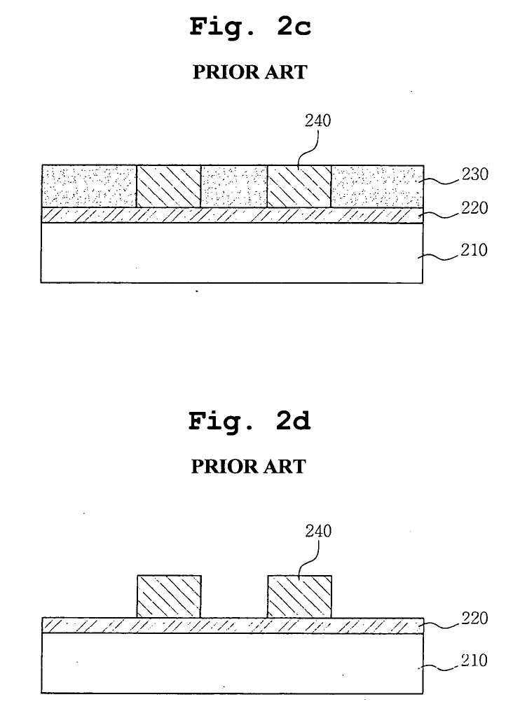

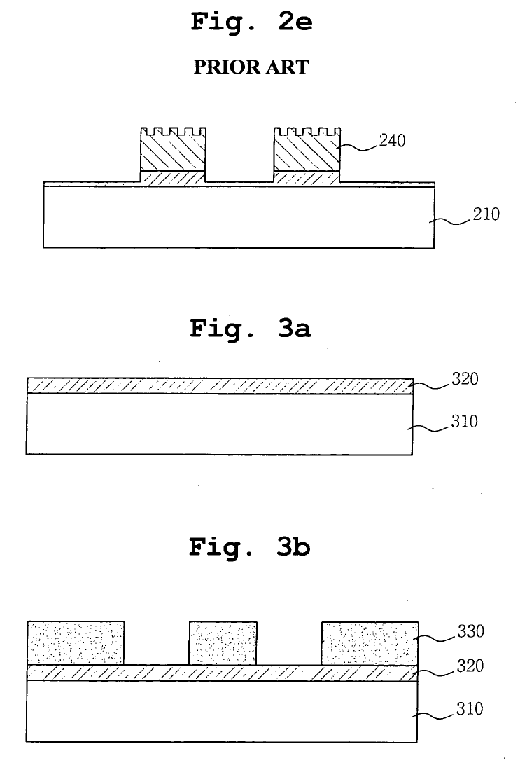

### DETAILED DESCRIPTION OF THE INVENTION

Hereinafter, a detailed description will be given of a method of forming a bump pad of a flip chip of the present invention, with reference to the appended drawings.

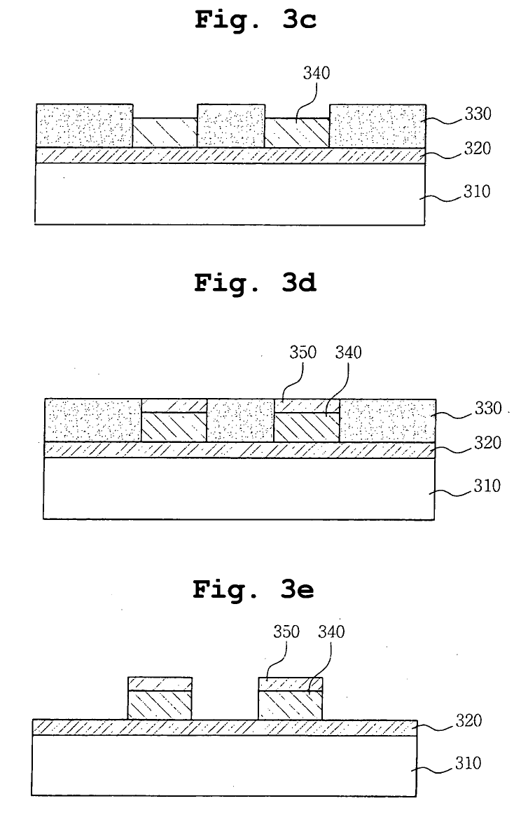

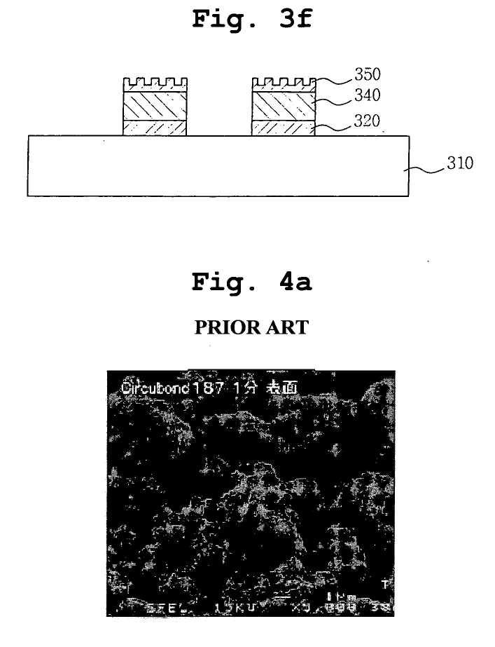

FIGS. 3a through 3f are sectional views sequentially showing the fabrication of the bump pad, according to the present invention.

As shown in FIG. 3a, an insulating layer 310 is plated via an electroless copper plating process, whereby a thin copper plating layer 320 is formed thereon, which can be electrically conducted.

The electroless plating or metal sputtering or metal sputtering or metal sputtering process is solely used to provide electroconductivity to the surface of the insulating material, such as resins, ceramics and glass.

Hence, the electroless copper plating is performed not by ionic reactions but by deposition reactions, in which the deposition is accelerated by a catalyst.

With the aim of depositing copper from a plating solution, the catalyst should be attached onto a material to be plated. This means that the electroless copper plating process requires numerous pre-treatments.

Further, the electroless copper plating process is disadvantageous in terms of being unused to form a thick plating film, and having inferior physical properties to electrolytic copper plating. In recent years, however, the electroless copper plating is further improved in the properties, and thus, has wider applications.

As for the electroless copper plating, a substrate is immersed into the plating solution, and thus, is entirely plated.

Such an electroless copper plating process comprises (1) defatting, (2) soft etching, (3) pre-treatment with catalyst, (4) catalyst treatment, (5) activation, (6) electroless copper plating, and (7) oxidation prevention.

As for the defatting process, oxides or impurities, in particular, fat components, present on a copper foil, are removed with an acid or alkali surfactant-containing chemical. In this case, it is important that the surfactant used is completely washed out with water.

As for the soft etching process, the surface of the copper foil is treated to have a fine roughness, whereby the copper particles are uniformly attached to the copper foil upon the plating process. Further, contaminants untreated by the defatting process may be removed.

As for the pre-treating process by catalyst, the substrate is previously immersed into a catalyst chemical having a lower concentration before the catalyst treating process, whereby contamination of the chemical or change of the concentration can be prevented.

Further, the above process functions to activate the following catalyst treatment by previously immersing the substrate into the same chemical bath, and uses the catalyst chemical diluted to 1-3%.

As for the catalyst treating process, the catalyst particles are coated onto the copper foil and the epoxy surface of the substrate. The catalyst particles are composed of Pd—Sn compound, in which Pd²⁻ is bonded with Cu²⁺ to be plated and acts as an accelerator.

As for the activating process, Pd and Sn are forcibly ionized in the state of Pd—Sn being coated on the substrate through the catalyst treatment to increase electroconductivity and affinity of the copper plating layer.

In this case, a filtering system to remove the Sn component should be required. The chemical reaction of the electroless copper plating includes deposition of copper, liquid decomposition, and stabilization.

To continue the plating process, the above three reactions should be balanced. For this, it is important that the composition of the plating solution is controlled, which is achieved by a proper feeding of an insufficient component, a mechanical stirring, and a circulation system of the plating solution.

In addition, the filtering system is utilized to treat the by-products of the reaction, whereby the plating solution can be further used for a prolonged period. On the other hand, the copper plating is divided into a heavy copper plating, a middle copper plating, and a light copper plating, depending on thickness of the plated copper.

As for the oxidation preventing process, an oxidation preventing film is coated to an entire surface of the plating film so that the film is prevented from oxidation by the alkali component remaining after the electroless copper plating.

Referring to FIG. 3b, a photosensitive material (dry film) is coated and then an imaging process is performed, thereby preparing a resist pattern 330.

The imaging process is carried out according to a series of lamination for coating of the photosensitive material, exposure to light and development, and also is classified into a photography and a screen printing.

In the photographic method, an artwork film having a wire pattern output is used. In addition, the photographic method is divided into a D/F method using the dry film as the photosensitive material, and a liquid photosensitive method using a liquid photosensitive material.

In the D/F method, a substrate having high adhesion of D/F by a face-to-face treatment is coated with D/F by use of a laminator. Upon the lamination, D/F is thermally compressed by use of a heated roller to further increase the adhesion with the substrate.

As such, while a cover film is stripped off, a Mylar film remains in the position to protect a photoresist film as the photosensitive material.

Upon the D/F lamination, contamination by impurities, such as dust, must be completely prohibited. Factors affecting the quality of the lamination process include temperatures of the compressive roller, compression rates and temperatures of the substrate.

For example, the temperatures of the compressive roller and the substrate are maintained in the range of 110±10° C. and 50-70° C., respectively.

As for the liquid photosensitive method of the photographic method to form the resist pattern, the liquid photosensitive material is coated on the substrate and dried, thus obtaining the same effects as the D/F coating. The liquid photosensitive material may be thinly coated, compared to the D/F method, and thus it is possible to form a finer circuit pattern.

In particular, the above photosensitive method is advantageous in that the substrate in the uneven surface state have increased uniformity by filling the liquid photosensitive material into recesses of the uneven surface, compared to the D/F method.

However, the photosensitive method suffers from drawbacks, such as contamination by dust, and difficult work. As well, it is difficult to perform a coating process to form a uniform thickness. At present, the usable coating method is exemplified by screen coating, dip coating, roll coating, and ED coating.

The liquid photosensitive material coated cannot be used as it is, and should be additionally dried in an oven.

The exposure means that the substrate is exposed to light. The substrate coated with D/F or liquid photosensitive material comes into close contact with the artwork film, and then is exposed to ultraviolet rays so as to react the photosensitive material with light.

When the substrate in close contact with the artwork film is exposed to ultraviolet rays, such rays are transmitted to the other portions, with the exception of the wire pattern portion. The D/F or liquid photosensitive material exposed to ultraviolet rays is cured by polymerization, while the other portions remain unchanged.

Factors affecting the exposure include an exposed amount, performance of an assistant vacuum tool for use in close contact of the artwork film, uniformity of the exposed amount, vacuum degree, exposed period, and the performance of an ultraviolet lamp.

The development process is used to dissolve and remove the other portions, with the exception of the portion exposed to ultraviolet rays and then cured. Through the development, the wire pattern on the artwork film appears on the substrate. A developing liquid is exemplified by sodium carbonate or potassium carbonate.

In cases of using the D/F, the Mylar film is removed before the development. After the development, the substrate is washed with water and dried to remove the developing liquid remaining thereon.

Although the wire pattern is observed but is not distinct after the exposure, it can be distinctly seen by selectively removing the photoresist through the development.

Factors affecting the development include concentration and temperature of the developing liquid, developing pressure, kinds of defoamer, pressure and temperature required for a water-washing process, ratio of the developing period to water-washing period, and drying temperature and period.

In addition to the photography as for the screen printing of the imaging process to prepare the resist pattern, the wire pattern is transcribed in a screen printing manner using a screen plate.

For this, the preparation of the screen plate is preceded. Below, a description will be given of a principle of a working procedure of a plate making, and then the printing method of the wire pattern using the screen.

The plate making is used to prepare the screen needful to print various patterns including the wire pattern. The procedure of the plate making is as follows. That is, a screen is spread on a frame for plate making. When the screen is spread, a manual tool or an automatic machine is used. The screen is uniformly spread on the frame as in a bias manner.

Then, four edges of the screen are uniformly pulled by use of a tension tool, and then fixed to the frame for plate making by use of an adhesive or a tape. The tension tool serves to apply tensile force using a pneumatic pressure.

To confirm whether the tensile force is uniform on the screen, a tension gauge is placed on the spread screen and measured for tensile force. When the wire pattern is printed on the screen having a non-uniform tensile force, the pattern is distorted, and thus, short wires or short circuits may occur.

Through the above procedure, when the screen is fixed to the frame for plate making, the wire pattern is formed on the screen.

Thereafter, defatting, coating of an emulsion, drying, preparation of the artwork film, exposure to light, development, drying and inspection are sequentially performed.

The defatting process is used to remove and wash fat components attached to the screen with a neutral detergent or weak alkali aqueous solution, to increase the adhesion of the emulsion in the following process.

As for the coating of the emulsion, both surfaces of the screen are simultaneously coated. In such cases, a coating thickness may be different according to end uses. The emulsion is exemplified by gelatin, bichromate of PVA, gelatin-iron salt, and diazo compounds.

After the coating of the emulsion, the screen is dried for the following exposure.

Then, the artwork film on which the wire pattern to be transcribed to the screen is output is prepared. Such an artwork film is in close contact with the screen and exposed to light by a light source, such as a mercury lamp.

Since the emulsion used for the screen is water soluble, the development process is carried out using water after the exposure. Thereby, the wire pattern appears on the screen.

The drying process is used to remove water used for the development. The inspecting process is used to confirm the state of the screen plate with the naked eyes, for instance, reproducibility, close contact and fixed state of the emulsion, and clearness of the pattern.

As for the screen printing to transcribe the wire pattern on the screen to the substrate in a printing manner, a resist ink is poured on the screen and passes through the screen with no patterns comprising meshes, by use of a rubber bar, so called a squeeze, and is smeared to the substrate below the screen. As such, since the ink does not pass through the pattern portion of the screen, the screen pattern is printed on the substrate.

The screen printing is referred to as ‘silk screen’ This is because the screen is initially made of silk. The major property of the screen printing is mass production.

The screen is mounted to the printer and the ink passes therethrough by use of the squeeze, whereby a desired pattern is transcribed to the substrate. Thus, the screen printing method has a drastically shortened working period, compared to the photographic method.

In the screen printing method, the squeeze is properly selected in consideration of the angle between the squeeze and the substrate, printing rate, and blade shape. The squeeze should have resistance to wear and solvent. Also, the squeeze is used in the state of being slanted at 50-80°, and is made mainly of a urethane rubber.

After completion of the screen printing, the resist ink is cured, in which the curing process means a drying process. For the drying process, the printed substrate is placed into a drying lack and dried under conditions according to the properties of the resist ink. Further, equipment for mass production may be utilized, capable of exclusively performing the total procedures from the screen printing to the drying.

The drying process includes room temperature drying, mild wind drying, electric heat drying, far infrared drying and ultraviolet drying. Of them, the drying process using far infrared rays is mainly used. Recently, the drying process using ultraviolet rays is adopted.

The ultraviolet drying process uses an ultraviolet lamp and is effective for only an ultraviolet ink. In particular, the drying time is in the range of several seconds and thus a working period is drastically shortened. Also, there is not required a large device, thus reducing the occupation area.

However, it should be noted that the resist ink is damaged by the pressure required for spraying of an etching solution upon the etching process, and thus, the copper foil to be protected may be etched, in cases where the drying process is insufficiently performed.

In FIG. 3c, a circuit is formed by an electrolytic copper pulse plating. As such, a plating layer 340 by the pulse plating has a thickness of 5-10 μm.

The pulse plating is an electroplating method using a pulse wave current. In contrast to the chemical synthesis, a given current density can be adjusted in the electrolytic process, and the reaction rate of the system can be controlled. Further, the driving force of the reaction can be easily controlled by the adjustment of an electrode potential. In recent electronic techniques, the above advantage of the electrolytic process is greatly improved by the current and potential applied to the function of time. The pulse plating has such advantages.

As practical waves, there are exemplified a cycle without current or a cathodic pulse by an anodic pulse, direction current (DC) having overlapped modulation, continuation of the cathodic pulse by continuation of the anodic pulse, galvanostatic or potentiostatic pulse, square wave or modulated sine wave pulse.

Main purposes of the pulse plating are to improve physical properties of a deposited material, such as porosity, softness, hardness, electroconductivity, wear resistance, and surface roughness. Further, the pulse plating results in alloy deposition of a composition and a structure that cannot be obtained by the DC plating. Also, a thickness distribution of the plating layer by polarity reversed periodically is improved, and an average deposition rate increases even though the pulse plating is performed under further limited conditions.

Thereafter, as shown in FIG. 3d, a DC plating layer 350 is deposited on the electroless pulse copper plating layer 340 by the DC plating.

The DC plating means that a metal is coated on the surface of the pulse plating layer using a direct current.

In cases where the pulse plating layer is plated with copper from a plating tank, a battery is a supply source of the direct current but is not practical. Commercially, a device called a rectifier is used to convert an alternating current (AC) to the direct current.

A part to be plated is connected to a negative terminal of the rectifier. Such a part is charged to a negative electrode, referred to as a cathode. The solution in the tank includes ionized copper.

Whereas, metal copper is connected to a positive terminal of the rectifier. Copper charged to a positive electrode is referred to as an anode: During the process, the metal copper anode is dissolved and the solution turns deep green.

At the cathode, the current flowing to the part surface acts to change the state of the copper in the solution, whereby the copper in the solution is deposited as the metal copper on the part.

The deposition amount of copper is controlled by a current quantity (ampere) and a time required to transfer the current to the part from the plating bath. The plating time is in the range of 10 to 30 min.

To control the thickness of the plating metal, a surface area of the part to be plated, which is represented by square feet, should be measured. Then, a voltage required for the desired thickness is properly applied to control the current and select the time.

An ASF means a current (ampere) flowing per 1 square feet of surface area, and is referred to as a current density. Each plating bath has a proper current density range. If too low a current is applied, the surface is insufficiently coated.

Meanwhile, if the current density is too high, the surface becomes rough and is grain coated. Zinc cyanide is controlled to an average current density of about 25 ASF, and an acid bath, such as acidic copper and nickel, is controlled to the current density higher than about 50 ASF.

As shown in FIGS. 3e and 3f, the resist pattern 330 and then the electroless copper plating layer 320 are removed, in that order.

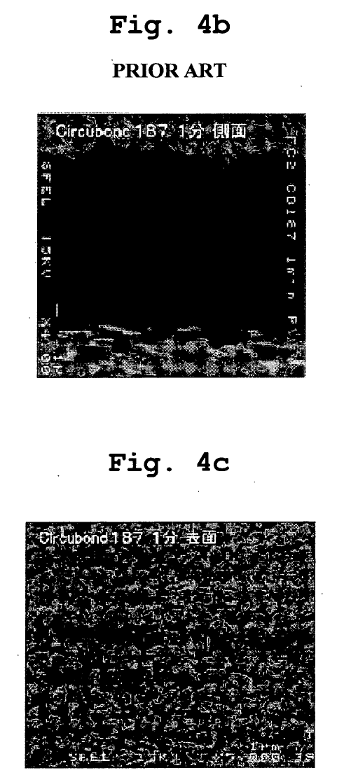

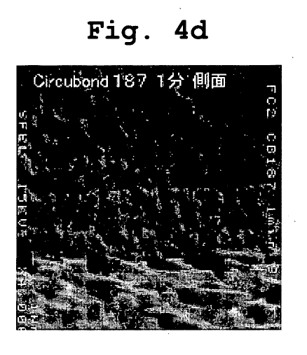

Turning now to FIGS. 4a and 4b, there are shown the surface and side surface of the copper plated deposition structure of the bump pad, according to the conventional technique, respectively. Additionally, FIGS. 4c and 4d shows the surface and side surface of the copper plated deposition structure of the bump pad, according to the present invention, respectively.

As shown in FIGS. 4a and 4b, since the conventional copper plated deposition structure is large when being seen from the surface and the side surface thereof, an intercrystalline etching process by an acid of a post process results in a drastically uneven surface. Hence, the flip chip is undesirably bonded, due to the uneven surface or solder resist remainder to the uneven surface.

However, as shown in FIGS. 4c and 4d, the copper plated deposition structure of the present invention is relatively small, compared to the conventional technique. Hence, even though an intercrystalline etching process is performed by an acid of a post process, the surface becomes a relatively even state. Consequently, the flip chip is bonded well, thus decreasing defective rates.

As described hereinbefore, the present invention provides a method of forming a bump pad of a flip chip and a structure thereof, which is advantageous in terms of fine circuits having an even surface, and a high density bump pad. Further, since the pad surface is even, a small solder resist opening can be made to easily remove the solder resist. Furthermore, the formation of the fine pad corresponding to a wire bonding is possible, attributable to the even pad.

Although the preferred embodiment of the present invention to form the bump pad of the flip chip and the structure thereof has been disclosed for illustrative purposes, those skilled in the art will appreciate that various modifications, additions and substitutions are possible. Therefore, it is to be understood that within the scope of the appended claims, the invention may be practiced otherwise than as specifically described.

1. A method of forming a bump pad of a flip chip, comprising:
a first step of subjecting a surface of an insulating layer to electroless copper plating to prepare an electroless copper plating layer, which is then coated with a photosensitive material;
a second step of exposing to light and developing the photosensitive material to prepare a resist pattern, which is then pulse plated to form a pulse plating layer;
a third step of subjecting the pulse plating layer to electrolytic copper plating using a direct current, to prepare a direct current plating layer; and
a fourth step of removing the resist pattern prepared at the second step and the electroless copper plating layer prepared at the first step.

2. The method as defined in claim 1, wherein the first step comprises the formation of the electroless copper plating layer by subjecting the surface of the insulating layer to electroless copper plating, and the coating of the photosensitive material on the electroless copper plating layer.

3. The method as defined in claim 2, wherein the photosensitive material coated on the electroless copper plating layer is 20 μm thick.

4. The method as defined in claim 2, wherein the photosensitive material coated on the electroless copper plating layer is a dry film.

5. The method as defined in claim 1, wherein the second step comprises the formation of the resist pattern through exposure to light and development of the photosensitive material, and the formation of the pulse plating layer by subjecting the resist pattern to electrolytic pulse plating.

6. The method as defined in claim 5, wherein the pulse plating layer is 5-10 μm thick.

7. A structure of a bump pad of a flip chip, comprising:
a thin electroless copper plating layer having a predetermined thickness and patterned on an insulating layer;
an electroless layer having a predetermined thickness and formed on the thin electroless copper plating layer; and
an electrolytic layer having a predetermined thickness and formed on the electroless layer.

8. The structure as defined in claim 7, wherein the electroless layer and the electrolytic layer are total 20 μm thick.

9. The structure as defined in claim 7, wherein the electrolytic layer is 5-10 μm thick.
